(19) United States
(12) Patent Application Publication
(10) Pub. No.: US 2008/0054379 A1
(43) Pub. Date: Mar. 6, 2008

(54) SEMICONDUCTOR DEVICE

(75) Inventors: Yoji Nishio, Tokyo (JP); Yutaka Uematsu, Tokyo (JP); Hideki Osaka, Tokyo (JP); Tsutomu Hara, Tokyo (JP); Seiji Funaba, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/675,476

(22) Filed: Feb. 15, 2007

(30) Foreign Application Priority Data
Feb. 16, 2006 (JP) 2006-039520

(51) Int. Cl. H01L 29/94

(52) U.S. Cl. 257/411

(57) ABSTRACT

Input circuit ensuring a noise margin for a reference voltage. A semiconductor chip 11a comprises a pad 14 that inputs a reference voltage Vref, an input circuit 13, a resistance element R1 connected between an input terminal of the input circuit 13 and the pad 14, a capacitance element C1 connected between the input terminal of the input circuit 13 and a power supply VDD, and a capacitance element C2 connected between the input terminal of the input circuit 13 and a ground VSS within the semiconductor chip. A resistance value of the resistance element R1 is set based on an impedance characteristic of a network, for supplying the reference voltage Vref.

### FIELD OF THE INVENTION

The present invention relates to a semiconductor device. More specifically, the invention relates to a semiconductor device that determines a logical value of an input signal by referring to a reference voltage.

### BACKGROUND OF THE INVENTION

Among semiconductor devices used in an information processing device or the like are those to which a reference voltage (Vref) is supplied from outside and which determines a logical value of an input signal, using a receiver, based on the reference voltage (Vref). The reference voltage is a voltage to be referred to. As an example of the semiconductor devices as described above, a memory chip such as a DRAM (Dynamic Random Access Memory) can be pointed out. When handling two logical values, for example, the semiconductor device as described above reads an input voltage larger than the reference voltage by a certain voltage as a logical value of and reads an input voltage smaller than the reference voltage by a certain voltage as a logical value of “0”.

Accompanying an increased speed of a signal handled by the semi conductor devices in recent years, a phenomenon is becoming manifest in which the semiconductor devices cause a malfunction due to a logic failure resulting from super imposition of noise on the reference voltage. In order to ensure a sufficient noise margin for a stable operation of these semiconductor devices, reduction of the noise on the reference voltage is essential.

Among conventional semiconductor device implementation technologies for reducing noise on a reference voltage, there is known a technique for inserting a resistance of a certain value or more into a power supply network, thereby changing vibration noise caused by the noise on the reference voltage from damping vibration to overdamping and suppressing fluctuation of a power supply in a short time (refer to Patent Document 1). There is also known a technique for adding an electrostatic capacitance to a reference voltage line, thereby eliminating the noise (refer to Patent Document 2).

### [Patent Document 1]

Japanese Patent Kokai Publication No. JP-P-2006-32823A

### [Patent Document 2]

Japanese Patent Kokai Publication No. JP-P-2000-113003A

### SUMMARY OF THE DISCLOSURE

The disclosures of these Patent Documents 1 and 2 are incorporated herein by reference thereto.

Analysis by the inventor of the present invention has clarified that there are the following five types of noise that have influence on the reference voltage:

(1) First noise is the one resulting from a DC drop, or a DC-like potential drop in the semiconductor device which handles binary logic, it is a common practice to set the reference voltage to an intermediate potential between a supply potential and a ground potential. When a resistance on a power supply path is large, however, a DC potential drop on this power supply path may increase. Thus, the reference voltage may be reduced (or increased) more than the intermediate potential that should be properly assumed.
(2) Second noise is common-mode ground and power supply noise, which is the noise induced on the reference voltage when a power supply and a ground fluctuate in phase. Noise induced, when outputs are simultaneously driven (Simultaneous Switching Output Noise: SSO noise) at a time of commanding a read from a semiconductor memory, for example, corresponds to this noise.
(3) Third noise is differential-mode ground and power supply noise, which is the noise induced on the reference voltage when the power supply and the ground fluctuate in an adverse phase. Ground and power supply noise induced when a core circuit in the semiconductor device is operated, for example, corresponds to this noise.
(4) Fourth noise is damping vibration noise, or the noise of a damping vibration type induced when a current has been excited on a reference voltage line by a switch in the core circuit or the like. Assume a power supply path in a reference voltage supply wiring of a semiconductor package or a semiconductor chip as an electrical circuit like a secondary circuit. Then, when a noise current generated in a power supply circuit satisfies a condition of under-damping vibration based on a formula of condition derived from an electric equation for the secondary circuit, this noise arises.
(5) Fifth noise is extraneous noise or the noise induced by a variation of a difference between the reference voltage and the ground (or power supply) potential, that has been induced outside the semiconductor chip. Crosstalk noise induced by electromagnetic coupling between the reference voltage line and a line adjacent to the reference voltage line, for example is pointed out as the fifth noise.

In a semiconductor device described in Patent Document 1, the resistance is inserted into a reference voltage supply wiring in series. Thus, when the resistance is too large, a DC-like voltage drop may occur at a portion where the resistance is inserted. A noise margin may be therefore narrowed in a DC manner. Further, using only the resistance, the reference voltage cannot follow a fluctuation of ground and power supply noise, and thus the semiconductor device may be adversely affected by a common-mode like fluctuation of the power supply and the ground.

This phenomenon will, be described using FIG. 9. Referring to FIG. 9, reference character Vddq shows a variation in a power supply potential, reference character Vss shows a variation in a ground potential, and reference character “Signal” shows a signal that follows a fluctuation of the variation Vddq, as an example of the signal (e.g. a signal with a return path therefor is the power supply rather than the ground). An original logical value of this Signal is shown in “Logical Value of Signal” (0110011). Reference character Vref 2 corresponds to the reference voltage in Patent Document 1. The reference voltage Vref does not follow external noise, and always tends to maintain a constant potential. For this reason, when the common mode noise induced by a large fluctuation of the power supply and the ground in phase is generated as shown in a time period B, the noise margin will be reduced (at a point B in FIG. 9).

On the other hand, when the damping vibration noise or noise with phases thereof inverted between the power supply and the ground occurs in a semiconductor device described in Patent Document 2 in which an electrostatic capacitance is added using the ground as a reference, the effect of reducing these types of noise is small.

This phenomenon will be described, using FIG. 9 again. Referring to FIG. 9, reference character Vref1 corresponds to a reference voltage in Patent Document 2. In this case, the voltage Vref1 fluctuates, following only the variation of the ground potential Vss. Accordingly, when the differential mode noise induced by a large fluctuation of the power supply and the ground of inverted phases as shown in a time period A occurs, the noise margin will be reduced (as shown at a point A in FIG. 9). This occurrence offers drawback in the art.

According to the present invention, the following solution is proposed.

In the present invention, a resistance element connected in series with a reference voltage line and a capacitance element inserted between the Vref line and at least one of a ground Vss and a power supply Vdd are appropriately combined. Reduction of noise on a reference voltage is thereby implemented. Specifically, by applying one of the following three techniques, a noise margin for the reference voltage at a receiver (input circuit) is ensured.

A first technique is based on a combination of a protective resistance connected in series with a reference voltage supply wiring and a compensation capacitance that uses both of a power supply and a ground as a reference.

A second technique is based on a combination of the protective resistance connected in series with a reference voltage supply network, a compensation capacitance that uses both of the power supply and the ground as a reference, and a resistance inserted between the compensation capacitance and the power supply or the ground.

A third technique is based on a combination of a variable protective resistance connected in series with a reference voltage supply network, with a value thereof changed by an operation of a semiconductor device and a compensation capacitance that uses one of the power supply and the ground as a reference.

In the first technique, both of the power supply and the ground are used as the reference for the compensation capacitance. Second noise and third noise are thereby reduced. Further, by employing a protective resistance having a predetermined value or more, fourth noise is reduced. Further, by combing the protective resistance and the compensation capacitance to form a low pass filter (Low Pass Filter: LPF), fifth noise is reduced. In addition, by selecting an appropriate resistance value of the protective resistance that is not too large, the first, noise is also reduced to a minimum.

The second technique is a technique by which the resistance value of the protective resistance that is present in series with the reference voltage line is reduced, and a correspondingly necessary resistance is inserted on a side of the capacitance, thereby allowing more reduction of a DC drop than by the first technique. Immunity to the extraneous noise, however, is lower than by the first technique.

In the third technique, the variable protective resistance is employed. Then, the resistance value of the variable protective resistance is changed according to the operation of the semiconductor device so that the noise induced by the operation of the semiconductor device is most reduced. The first noise, second noise, third noise, fourth noise, and fifth noise are thereby reduced.

More specifically, a semiconductor device according to a first aspect of the present invention comprises:

an input terminal that receives a reference voltage;

an input circuit;

a first resistance element connected between an input end (node) of the input circuit and the input terminal;

a first capacitance element connected between the input end and a power supply line within the semiconductor device; and

a second capacitance element connected between the input end and a ground line within the semiconductor device.

In the semiconductor device according to a first development, it is preferable that a resistance value of the first resistance element is set based on impedance characteristic of a wiring for supplying the reference voltage.

In the semiconductor device according to a second development, it is preferable that a resistance value of the first resistance element is set to a largest resistance value among:

(a) a first resistance value of the first resistance element that causes a cut-off frequency of a low-pass filter formed of the first resistance element and the first and second capacitance elements connected in parallel to a clock frequency of the semiconductor device;
(b) a second resistance value of the first resistance element that causes a secondary circuit of a power supply wiring formed of a reference voltage line and a ground line to satisfy a requirement for over damping; and
(c) a third resistance value of the first resistance element that causes a secondary circuit of a power supply wiring formed of a reference voltage line and a power supply line to satisfy a requirement for overdamping.

In the semiconductor device according to a third development, the first capacitance element may be replaced by a series connection circuit formed of the first capacitance element and a second resistance element, and the second capacitance element may be replaced by a cascade connection circuit formed of the second capacitance element and a third resistance element.

In the semiconductor device according to a fourth development, it is preferable that a capacitance ratio between the first capacitance element and the second capacitance element is set based on a noise sensitivity of the input circuit.

In the semiconductor device according to a fifth development, it is preferable that the capacitance ratio is a ratio between a noise immunity voltage when a voltage level at the input end of the input circuit assumes a level on a ground side, and a noise immunity voltage when the voltage level at the input end of the input circuit assumes a level on a power supply side.

In the semiconductor device according to a sixth development, it is preferable that a sum of resistance values of the first and second resistance elements is a value that causes a secondary circuit of a power supply wiring formed of a reference voltage line and the power supply line to satisfy a requirement for overdamping; and

a sum of resistance values of the first and third resistance elements is a value that causes a secondary circuit of a power supply wiring formed of the reference voltage line and the ground line to satisfy a requirement for overdamping.

A semiconductor device according to a second aspect of the present invention comprises:

an input terminal that receives a reference voltage;

an input circuit;

a variable resistance element connected between, an input end of the input circuit and the input terminal;

a capacitance element connected between the input end and a power supply line or a ground line within the semiconductor device; and

a resistance control circuit that controls a resistance value of the variable resistance element.

In the semiconductor device according to a seventh development, it is preferable that the variable resistance element comprises a MOS transistor with a voltage at a control terminal thereof controlled by the resistance control circuit.

In the semiconductor device according to an eighth development, it is preferable that the resistance control circuit performs controls so that a resistance value of the variable resistance element assumes at least two values of:

a resistance value of the variable resistance

element that causes a cut-off frequency of a low-pass filter formed of the variable resistance element and the capacitance element to become a clock frequency of the semiconductor device; and

a resistance value of the variable resistance element that causes a secondary circuit of a power supply wiring formed of a reference voltage line and the power supply line to satisfy a requirement for overdamping when the capacitance element is connected to the power supply line, and causes a secondary circuit of a power supply wiring formed of the reference voltage line and the ground line to satisfy a requirement for overdamping when the capacitance element is connected to the ground line.

In the semiconductor device according to a ninth development, it is preferable that the resistance control circuit controls the resistance value of the variable resistance element according to an operation mode of the semiconductor device.

In the semiconductor device according to a tenth development, the semiconductor device is a DRAM and the operation mode is specified by a command for the DRAM.

In the semiconductor device according to an eleventh development, it is preferable that the resistance control circuit controls the resistance value of the variable resistance element according to a time elapsed following generation of the command.

In the semiconductor device according to a twelfth development, it is preferable that the resistance control circuit performs control so that when the command belongs to a first command group, the resistance value of the variable resistance element is reduced during execution of the command, and when the command belongs to a second command group, the resistance value of the variable resistance element is reduced during a certain period of time after a predetermined time has passed since the execution of the command.

The meritorious effects of the present invention are summarized as follows.

According to the present invention, noise on the reference voltage is reduced, and a noise margin for the reference voltage in an input circuit can be ensured at a higher extent. Accordingly, stability in the high-speed operation of the semiconductor device can be further improved.

### BRIEF DESCRIPTION OF THE DRAWINGS

FIG. 1 is a circuit diagram showing a main portion of a semiconductor device according to a first example of the present invention;

FIG. 3 is a block diagram, showing a configuration of a semiconductor device having two Vref inputs, according to the first example of the present invention;

FIGS. 3A and 3B include diagrams showing a concept of a method of measuring an immunity voltage according to a second example of the present invention;

FIG. 4 is a circuit diagram showing a main portion of a semiconductor device according to a third example of the present invention;

FIG. 5 is a block diagram showing a configuration of a semiconductor device having two Vref inputs according to the third, example of the present invention;

FIG. 6 is a circuit diagram showing a main portion of a semiconductor device according to a fourth example of the present invention;

FIG. 7 is a circuit diagram showing a specific configuration of a variable resistance element according to the fourth example of the present invention;

FIGS. 8A and 8B include diagrams showing time charts of resistance value control over the variable resistance element by a resistance control circuit;

FIG. 9 is a diagram showing noise waveform variations;

FIG. 10 is a circuit diagram for explaining a principle under which Off-Chip SSO noise is induced;

FIG. 11 is a circuit diagram for explaining a principle under which On-Chip SSO noise is induced; and

FIG. 12 is a diagram showing a waveform of the On-chip SSO noise induced in an underdamped state.

### PREFERRED MODES OF THE INVENTION

Before describing examples, among five types of noise listed in the section of the problem, principles under which the types of noise in items (2), (3), and (4) are induced will be described. The reason for this description is that behaviors of these types of noise greatly affect selection of a resistance value and capacitance arrangement. After the discussion on these three types of noise, requirements on a receiver side for reducing the types of noise in items (1) and (5), and the items (2), (3), and (4), respectively will be summarised. Finally, the examples for implementing reduction of those types of noise will be described.

Initially, the principles under which the types of noise in the items (2), (3), and (4) are induced will be explained. First, in order to explain about the types of noise in the items (2) and (3) among the types of noise in the items (2), (3), and (4), noise induced when outputs are simultaneously driven (Simultaneous Switching Output noise: SSO noise) will be taken as an example. As described in Patent Document 1, there are two types of noise in the SSO noise, which are Off-chip SSO noise and On-chip SSO noise. The Off-chip SSO noise is induced when a steep current flows from a power supply system to a signal path. The On-chip SSO noise is induced when a current flows into a power supply circuit loop due to an operation of a core circuit within a chip.

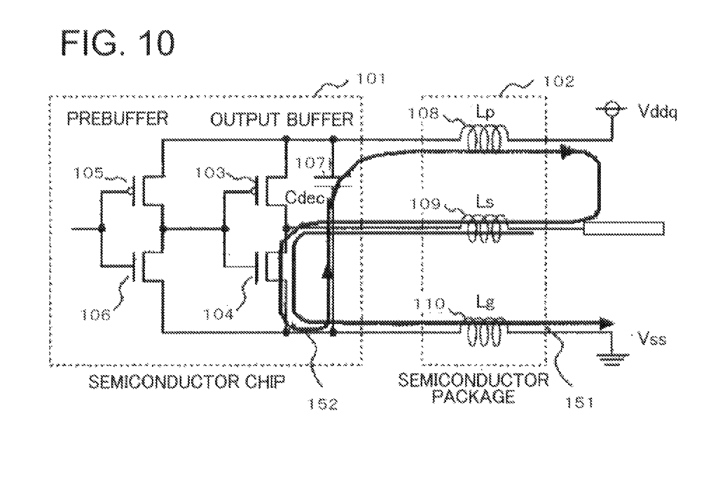

First, the principle under which the Off-Chip SSO noise is induced will be described, referring to FIG. 10. FIG. 10 shows a schematic diagram of an internal circuit of a semiconductor device that transmits an electrical signal to outside of a chip by switching of a CMOS circuit in an output buffer. The semiconductor device is formed of a semiconductor chip 101 and a semiconductor package 102 with the semiconductor chip 101 sealed therein, A supply voltage Vddq is supplied from a system, board, based on a reference of a ground potential Vss. In FIG. 10, for simplification of the drawing, only one stage of the output buffer using the CMOS circuit (formed of a PMOS transistor 103 and an NMOS transistor 104) and only one stage of a prebuffer using a CMOS circuit (formed of a PMOS transistor 105 and an NMOS transistor 106) are shown. However, actually, a plurality of output buffers and prebuffers are present, it is assumed that the noise, which, has currently posed the problem, is induced when a lot of CMOS devices are switched simultaneously in the same direction. Accordingly, only one set of the circuits is shown. Further, in regard to power supply lines in the semiconductor package, a sole power supply line obtained by bringing power supply lines into one power supply line and a sole ground line obtained by bringing ground lines into one ground line are shown, for simplification of the drawing. However, actually, power supply is often performed using a plurality of the lines.

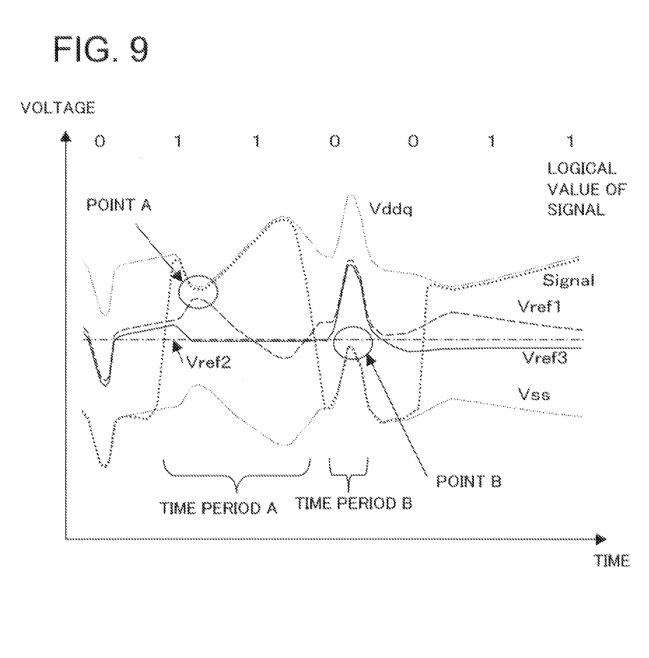

Now, a ease where an output of the CMOS circuit in the output buffer has been switched from high to low will, be considered. Since a signal line and a ground Vss are short-circuited in this case, an electric charge stored in the signal line flows like a current 151. When an on-chip capacitor 107 of the semiconductor chip has a sufficiently large capacitance, a current such as a current 152 flows through a power supply, the ground, and the signal line in order to maintain a potential difference between the power supply voltage Vddq and the ground potential Vss within the chip to be constant. A product of a time rate of change of the current in this ease and an inductance associated with power supply and ground portions of the semiconductor package is generated as voltage, resulting in ground and power supply noise. As seen from FIG. 10, the switching currents that flow through the power supply and the ground change temporally in the same direction. As a result, the ground and power supply noise induced in this case will exhibit a behavior of the common mode noise as shown in a waveform in a time period B in FIG. 9. The above is the description of the principle under which the Off-Chip SSO noise is induced and a waveform of the Off-Chip SSO noise. This is a typical example of the common-mode ground and power supply noise.

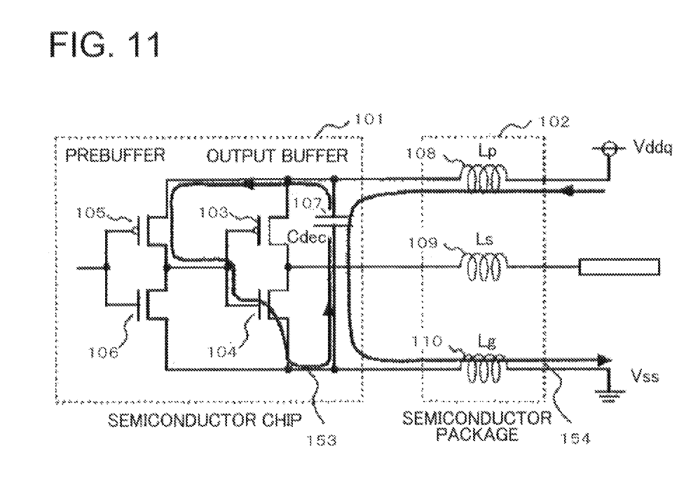

Next, the On Chip SSO noise will be described, with reference to FIG. 11. A circuit shown in FIG. 11 is the same as the circuit in FIG. 10, and a description of the circuit will be therefore omitted. Now, a case where the output of the CMOS circuit in the output buffer is being switched from high to low will be considered. When the output buffer is high, the prebuffer is low. At this point, a drain-to-source capacitance of the PMOS transistor 103 is discharged (because there is no drain-to-source potential difference), and a drain-to-source capacitance of the NMOS transistor 104 is charged. On the other hand, in the prebuffer, a capacitance of the PMOS transistor 105 is charged, and a capacitance of the NMOS transistor 106 is discharged. Next, an electric charge flow when the output is switched from high to low will be considered. In order to switch the output to low, the NMOS transistor 104 of the output buffer is turned on. Thus, the PMOS transistor 105 of the prebuffer is turned on. With this arrangement, an electric charge charged in the capacitance of the PMOS transistor 105 in the prebuffer is discharged, in order to charge the electric charge of the PMOS transistor 105 which has been lost by this discharging, an electric charge is supplied from the on-chip capacitor 107, which is an electric charge storage nearest to the prebuffer. An electric current path at this point is shown as a current 153 in FIG. 11. An electric charge amount in the on-chip capacitor 107 temporarily becomes insufficient for this purpose, and an electric charge is supplied from a power supply line for replenishment. That is, through the power supply line and the ground line of the semiconductor package 102, art electric current passes through a path as shown by a current 154. The on-chip capacitor 107 is thereby charged. In the wiring of the semiconductor package 102, the inductance is predominant. Further, a wiring inductance within the chip is very small, so that it can be almost negligible. An equivalent circuit of the current path through which the current 154 passes can be regarded as an RCL series secondary circuit in which a wiring inductance Lpkg (=Lp+Lg) of the semiconductor package 102, a capacitance Cdec of the on-chip capacitor 107 of the semiconductor chip 101, and a low wiring resistance Rpg are connected in series. Mathematically, it has been already known that in the circuit as described above, a circuit equation as shown in the following formula (1) holds:

d²Vc/dt²+Rpg/Lpkg*dVc/dt+1/(Lpkg*Cdec)*Vc=0 (1)

where, Vc indicates a potential difference between electrodes of the on-chip capacitor 107.

Now, the following two parameters are newly defined:

ω0≡1/sqrt(Lpkg*Cdev) (2)

α≡Rpg/(2*Lpkg) (3)

A parameter (Quality factor) Q that indicates quality of the circuit is expressed as shown in Formula (4) using ω0 defined by Formula (2) and α defined by Formula (3).

Q≡ω0/(2α)=sqrt(Lpkg/Cdec)/Rpg=ω0*Lpkg/Rpg (4)

Due to value of this factor Q and a magnitude relation relative to ½, a zero-order input response exhibits the following three behaviors:

First, when the factor Q is larger than ½, underdamping occurs. Thus, a current as given by Formula (5) flows through the circuit.

I=I0*exp(−αt)*cos(ωd*t+φ) (5)

where I0 indicates a maximum current amplitude value determined by a circuit voltage initial state, inductance, and capacitance, φ indicates the phase, and ωd indicates the angular frequency defined by the following Formula (6).

ωd≡sqrt(ω0²−α²) (6)

When the current as described above flows through the power supply line, voltage noise given by the following Formula (7) is induced in the inductance of the power supply and the ground, respectively:

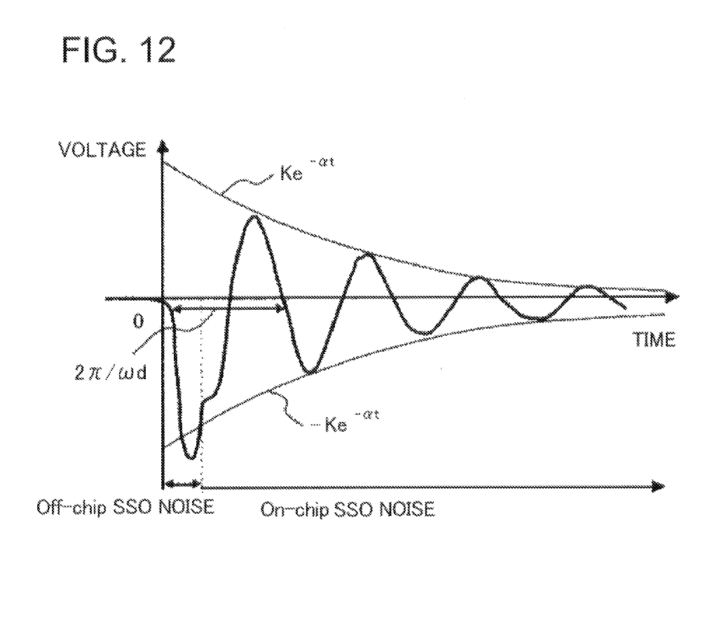

Vsso=k*exp(−αt)*sin(ωd*t+φ) (7)

where k indicates a maximum noise amplitude. This formula is obtained because the voltage generated in the inductance is determined by the product of the inductance and a time differentiated value of the current. A waveform of the On-chip SSO noise induced in a state of the underdamping will be shown in FIG. 12.

When the wiring resistance Rpg of 200 mΩ, capacitance Cdec of 500 pF, and wiring inductance of Lpkg of 1 nH are given as physical quantities with respect to a general semiconductor chip and a general semiconductor package, the factor Q becomes far larger than ½, which means a state of the underdamping (i.e., insufficient damping). A damping time τ(=1/α), which is a time required for the noise to be settled down becomes approximately 10 ns. This corresponds to a lime as long as 10 periods of a 1 GHz signal.

On contrast with the noise induced by the underdamping, a state where noise vibration quickly becomes settled, down is referred to as overdamping. A condition for achieving this state is the factor Q being smaller than ½. A boundary state between the underdamping and the overdamping is referred to as “critical damping”. A condition for achieving this state is the factor Q being equal to ½.

When noise caused by one of these three states described above is induced on the power supply line, noise arises on a signal line of the output buffer that shares the power supply (line) and the ground (line), which offers a problem.

Since the power supply and ground lines are usually designed to have a low resistance, the wiring resistance Rpg is small. For this reason, the factor Q becomes far larger than ½, and the circuit is in the underdamped state. Thus, the On-chip SSO noise as shown in FIG. 12 is generated. Further, a polarity of this noise shows a temporal change which becomes opposite between the power supply side and the ground side, as seen from a flow of the current in FIG. 11. Thus, this noise shows differential noise waveforms with phases thereof inverted to each other. This becomes a waveform as shown in the time period A in FIG. 9.

The above is the description about the principle under which the On-Chip SSO noise is induced and the waveform of the On-Chip SSO noise. This is a typical example of the differential-mode ground and power supply noise.

Finally, in regard to the description of the noise in item (4), the noise in item (4) may be considered to be the On-Chip SSO noise described above applied to a reference voltage Vref. This noise occurs when a noise current generated in the power supply circuit satisfies a condition of underdamping vibration due to discharging and charging of the capacitance (such as parasitic capacitance and/or compensation capacitance) between the reference voltage Vref and the potential. Vss (or Vddq) based on a formula of condition derived from an electric equation for the secondary circuit of the power supply wiring.

The above descriptions were directed to the types of noise in the items (2), (3), and (4). Requirements against the types of noise in the items (1) through (5) in an input circuit (receiver) based on these descriptions are summarised as follows:

(1) A requirement against a DC drop at the receiver is that the DC drop should be as small as possible. In order to achieve this requirement, a DC resistance value in a Vref power supply wiring should not be too large.

(2) With respect to the common-mode ground and power supply noise, it is required that the voltage Vref at the receiver fluctuates in phase with the fluctuation of the power supply or the ground. The voltage Vref1 shown in FIG. 9 fluctuates together (in parallel) with the ground potential Vss. It can be seen that at this point of state, the noise margin becomes the largest in the time period B where the common mode noise is induced.

(3) With respect to the differential mode ground and power supply noise, it is required that the voltage Vref assumes an intermediate potential between the power supply and ground potentials. This is like the state of the voltage Vref 2 shown in FIG. 9. It can be seen that at this point of the state, the noise margin becomes the largest in the time period A where the differential mode noise is induced.

(4) With respect to the damping vibration noise, it is required that an electrical parameter of the secondary circuit in a Vref supply wiring satisfies the condition of overdamping.

(5) With respect to the extraneous noise, it is required that a main frequency component of the extraneous noise is not entered into a receiver circuit.

A semiconductor device that satisfies most of the requirements as described above comprises an input terminal that receives a reference voltage, an input circuit (receiver circuit), a resistance element connected between an input end of the input circuit and the input terminal, and one or two capacitance element or elements connected between the input end and the power supply line or/and ground line of the semiconductor device, i.e., in case where two capacitance elements, each connected between the input end and the power supply line of the semiconductor device and between the input end and the ground line of the semiconductor device. The semiconductor device configured as described above can reduce the noise on the reference voltage at the input end of the input circuit and can therefore improve the noise margin of the reference voltage. A detailed description will be given in connection with examples with reference to appended drawings.

### EXAMPLE 1

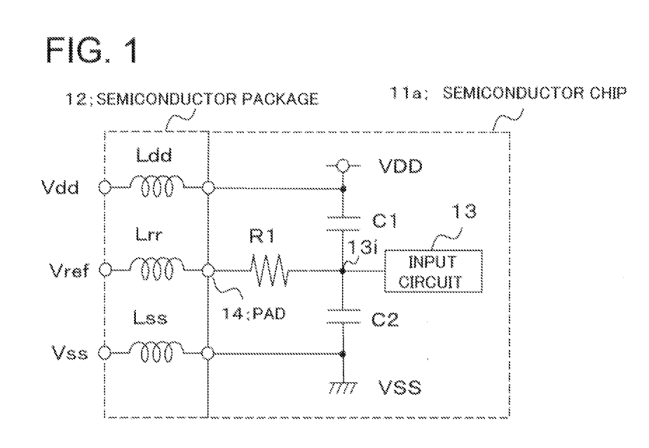

FIG. 1 is a circuit diagram showing a main, portion of a semiconductor device according to a first example of the present invention. Referring to FIG. 1, the semiconductor device includes a semiconductor chip 11a and a semiconductor package 12 that includes the semiconductor chip 11a. The semiconductor chip 11a includes an input circuit 13, a pad (or node) 14 that receives a reference voltage, a resistance element R1 inserted between the pad 14 and an input end 13i of the input circuit 13, a capacitance element C1 inserted between the input end 13i of the input circuit 13 and a power supply VDD, and a capacitance element C2 inserted between the input end 13i of the input circuit 13 and a ground VSS. Herein, a resistance value of the resistance element R1 is indicated by Rrr, a capacitance of the capacitance element C1 is indicated by Crd, and a capacitance of the capacitance element C2 is indicated by Crs. Incidentally, though other various circuits are included on the semiconductor chip 11a, these circuits are not related to the present invention. Thus, descriptions of the other various circuits will be omitted.

On the semiconductor package 12, a self inductance Ldd is present on a line that interconnects the power supply VDD of the semiconductor chip 11a and an external power supply Vdd, a self inductance Lrr that interconnects the pad 14 of the semiconductor chip 11a and an external reference voltage Vref, and a self inductance Lss that interconnects the ground VSS of the semiconductor chip 11a and an external ground Vss.

The semiconductor device configured as described above implements a first technique for solving the problem. It is preferred that herein, magnitudes of the two capacitances Crd and Crs are set to be equal and the resistance value Rrr assumes the largest value among the following three values:

Rrr1=1/[2π(Crd+Crs)fck] (8)

Rrr2=2[(Lrr+Lss)/Crs]^{0.5} (9)

Rrr3=2[(Lrr+Ldd)/Crd]^{0.5} (10)

where fck is a clock frequency used in the semiconductor device. However, when it is self evident that Vref noise having a specific frequency fp, which is not higher than the clock frequency, is large in a system incorporating the semiconductor device of interest, it is preferred that this frequency fp is used in place of the clock frequency fck in Formula (8).

With respect to each of the resistance values, the resistance value Rrr1 denotes a resistance value that causes a characteristic frequency of an RC filter to assume the clock frequency so that the noise of the clock frequency is cut off by an LPF formed by the protective resistance and the capacitance(s) The resistance value Rrr2 denotes a resistance value that causes the secondary circuit in the power supply wiring formed of a Vref line and the ground line to satisfy the requirement for overdamping. The resistance value Rrr 3 denotes a resistance value that causes the secondary circuit in the power supply wiring formed of the Vref line and the power supply line to satisfy the requirement for overdamping.

When the resistances Rrr1, Rrr2, Rrr3 are found in a semiconductor device, for instance, with a capacitance Crd of 5 pF, a capacitance Crs of 5 pF, a clock frequency fck of 500 MHz, an inductance Lrr of 3 nH an inductance Lss of lull, an inductance Ldd of 1 nH, the resistances Rrr1, Rrr2, and Rrr 3 are computed to be 31. 8Ω, 56. 6Ω, and 56. 6Ω which is equal, to the resistance value Rrr2, respectively. When the largest resistance value is selected in this case, it is preferred that the resistance value Rrr is set to approximately 56. 6Ω.

Next, the reasons why the types of noise in the items (1) to (5) are reduced by configuring the semiconductor device as described above will be explained.

### (1): By setting the resistance value Rrr to an appropriate value, without using an excessively large value, the DC drop in item (1) can be made to be as small as possible.

(2), (3): The common mode noise in item (2) and the differential mode noise in item (3) fluctuate so that the common mode noise and the differential mode noise always maintain intermediate potentials against each fluctuation of the power supply and the ground, respectively, due to an effect of the capacitances that use both of the power supply and the ground as a reference. Thus, the common mode noise and the differential mode noise pose no problem.

### (4): The damping vibration noise in item (4) poses no problem because the value of the resistance value Rrr is selected so that the Vref supply wiring satisfies the requirement for overdamping.

(5): The extraneous noise in item (5) poses no problem because the clock frequency and high harmonic components thereof, which mainly constitute the extraneous noise, are cut off by the low-pass filter that uses a combination of the protective resistance Rrr and the capacitances.

As described above, the effect of reducing the types of noise in the items (1) to (5) can be achieved.

The above description was directed to a case where one kind of the reference voltage Vref is input. The invention is not limited to this, and two or more kinds of the reference voltage Vref may be input. FIG. 2 is a block diagram showing a configuration of a semiconductor device having two Vref inputs. Referring to FIG. 2, reference numerals that are the same as those in FIG. 1 indicate same components, A semiconductor chip 11b includes a capacitance element C2a that connects an input end 13ai of an input circuit 13a and the ground VSS, a capacitance element C1a that connects the input end 13ai of the input circuit 13a and the power supply VDD, and a resistance element R1a that connects the input end 13ai of the input circuit 13a and a pad 14a. The semiconductor chip 11b further includes a capacitance element C2b that connects an input end 13bi of an input circuit 13b and the ground VSS, a capacitance element C1b that connects the input end 13bi of the input circuit 13b and the power supply VDD, and a resistance element R1b that connects the input end 13bi of the input circuit 13b and a pad 14b. The semiconductor package 12a further includes a line having a self inductance Lrra that gives a reference voltage Vrefa to the pad 14a and a line having a self inductance Lrrb that gives a reference voltage Vrefb to the pad 14b.

In the semiconductor chip 11b having the configuration as described above, a resistance value of the resistance element R1a should be set according to the self inductance Lrra and a difference between capacitances of the capacitance elements C1a and C2a, and a resistance value of the resistance element R1b should be set according to the self inductance Lrrb and a difference between capacitances of the capacitance elements C1b and C2b, A method of determining the resistance values of the resistance elements R1a and R1b is the same as that as described before. Herein, the description was directed to the case where the two kinds of the reference voltage Vref are input. When three or more kinds of the reference voltage Vref are input, the same method may be used for setting.

### EXAMPLE 2

A semiconductor device according to a second example is the semiconductor device which has the same configuration as in FIG. 1, and in which Vref sensitivity of the input circuit 13 differs between a high level side and a low level side. A capacitance of the capacitance element C1 is indicated by Crd and a capacitance of the capacitance element C2 is indicated by Crs, and the capacitance Crd is set not to be equal to the capacitance Crs.

When the capacitance Crd is not equal to the capacitance Crs, noise immunity (or noise-resistant) voltages of the receiver circuit are measured both on the high and low level sides, respectively, and a ratio between, the capacitances Crd and Crs is determined according to a ratio between their noise immunity voltages, A noise immunity voltage herein refers to a maximum voltage at which the receiver can properly perform a read/write operation when sine-wave noise with a predetermined frequency is input between the Vref and Vss (or Vdd) lines. The noise immunity voltage on a high level side refers to a voltage at which a high-level logic signal can be properly read and written, while the noise immunity voltage on the low level side refers to a voltage at which a low-level logic signal can be properly read and written. Preferably, the predetermined frequency used when evaluating the immunity voltage is appropriately 1 MHz. It is because at the frequency of such a degree, an influence of an RC filter naturally formed within the chip (caused by a wiring resistance and parasitic capacitance) is small, so that original characteristics of the receiver per se are reflected.

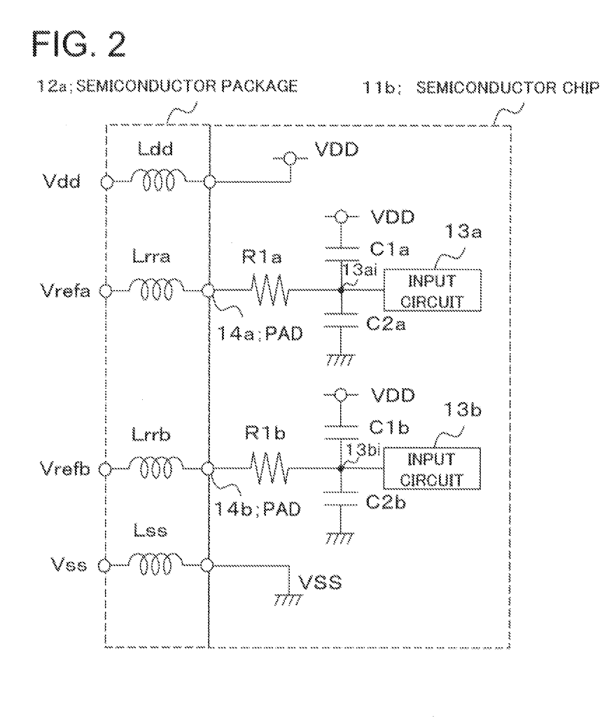

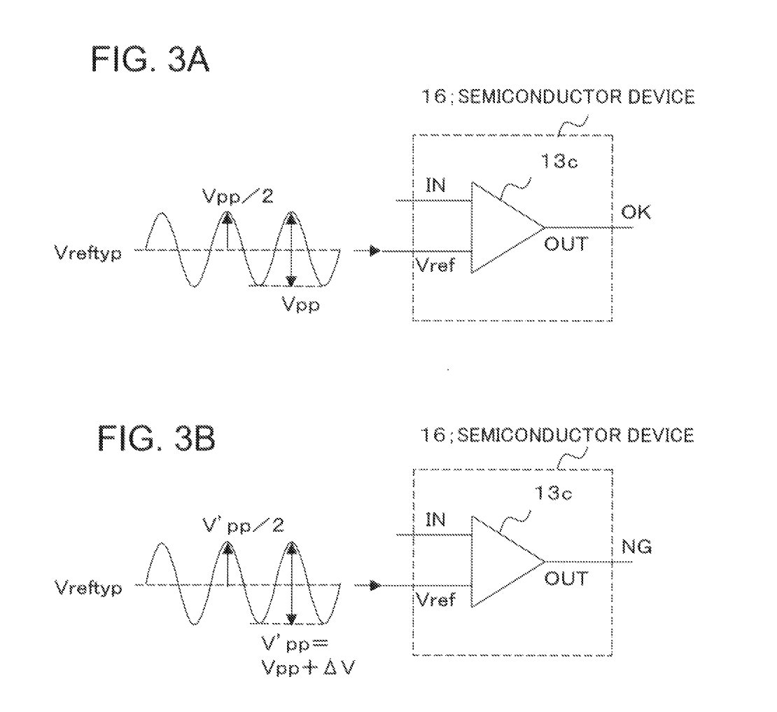

A conceptual diagram of a method of measuring the noise immunity voltage as described above will be shown in FIGS. 3A and 3B. As shown in FIGS. 3A and 3B, a data signal is supplied to a data input terminal of the semiconductor chip with a sine-wave voltage having an amplitude Vpp applied to a Vref input terminal of a semiconductor device 16 as a center voltage Vreftyp (a Vref standard value specified in specifications). Repetitive patterns of logical values of “0 and 1” are given to data with such a sine-wave amplitude applied as the voltage Vref, and written and read by an input circuit 13c. When read data is checked, and when a value different from a logical value given at a time of the writing operation is read, it means that an error has occurred (as shown in FIG. 3B). A minimum, value of half a value of the amplitude (a half amplitude of) Vpp of a sine-wave noise voltage that causes the error as described above is the immunity voltage. A voltage having an amplitude V′pp/2 when a logic on the low level side has caused an error for the first time is the noise immunity value on the low level side, while a voltage having the amplitude V′pp/2 when a logic on the high level side has caused an error for the first time is the noise immunity voltage on the high level side. When receiver sensitivities are symmetrical, the noise immunity voltages on the low and high level sides are the same. However, when the receiver sensitivities are asymmetrical, the noise immunity voltages on the low and high level sides become different to each other.

If determination of the capacitances Crd and Crs is carried out according to an inverse ratio of the noise immunity voltage on the high level side to the noise immunity voltage on the low level side. It can provide a wider margin to the side having the smaller noise immunity voltage, and the noise margin as a whole is enlarged. As an example of this determination, when there is a receiver for which a ratio of the noise immunity value on the high level side to that on the low level side is 1 to 2, the ratio of the capacitance Crd to the capacitance Crs should be set to two to one.

As described above, by determining the balance between capacitance values according to the sensitivities of the input circuit (receiver), the noise margin can be secured to be larger than in the first example when the receiver sensitivities are asymmetrical.

### EXAMPLE 3

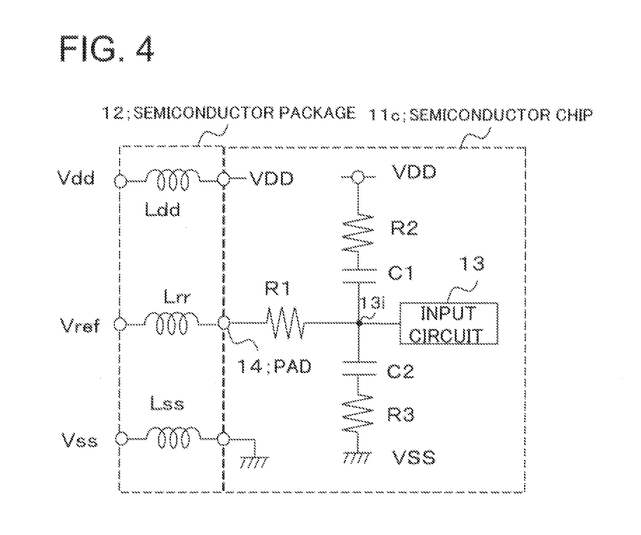

FIG. 4 is a circuit diagram showing a main, portion of a semiconductor device according to a third example of the present invention. Referring to FIG. 4, same reference numerals as those in FIG. 1 indicate same components. In a semiconductor chip 11c in FIG. 4, a resistance element R2 is added between the capacitance element C1 and the power supply VDD, and a resistance element R3 is added between the capacitance element C2 and the ground VSS. Resistance values of the resistance elements R2 and R3 are indicated by Rrd and Rrs, respectively. The semiconductor device having a configuration as described above serves to reduce the resistance value Rrr of the resistance element R1 as much as possible, and allow reduction of an influence of the DC drop. Specifically, when the resistances that satisfy Formulae (9) and (10) which are requirements for overdamping are too large, the semiconductor device effectively reduces the DC drop.

That is, in order to satisfy the requirements for overdamping, the following formulae become conditions when the resistances are selected.

Rrr2=Rrr+Rrs=2[(Lrr+Lss)/Crs]^{0.5} (11)

Rrr3=Rrr+Rrd=2[(Lrr+Ldd)/Crd]^{0.5} (12)

For instance, when the resistance values Rrr1, Rrr2, Rrr3 are found in the semiconductor device with a capacitance Crd of 2 pF, a capacitance Crs of 2 pF, a clock frequency fck of 1 GHz, a inductance Lrr of 5 nH, an inductance Lss of 2 nH, an inductance Ldd of 2 nH, the resistance values Rrr1, Rrr2, and Rrr 3 assume 39. 8Ω, 118. 3Ω, and 118. 3Ω (=Rrr2), respectively. Accordingly, in the first example, the resistance value Rrr needs to be set to approximately 118. 3Ω. In this example, however, it suffices to set the resistance values Rrr, Rrs, and Rrd to 39. 8Ω, 78. 5Ω, and 78. 5Ω that is equal to the resistance value Rrs, respectively. The smaller the Rrr becomes, the more the DC drop of the reference voltage Vref received by the input circuit 13 can be reduced. Herein, however, it should be noted that characteristics of an LPF formed of a resistance R and a capacitance C are degraded. That is, the noise damping at an LPF portion can be performed at a filter portion only to an extent of Rrs (or Rrd)/{Rrs (or Rrd)+Rrr}. For this reason, this example is effective when an influence of the extraneous noise is small and the damping vibration noise is large.

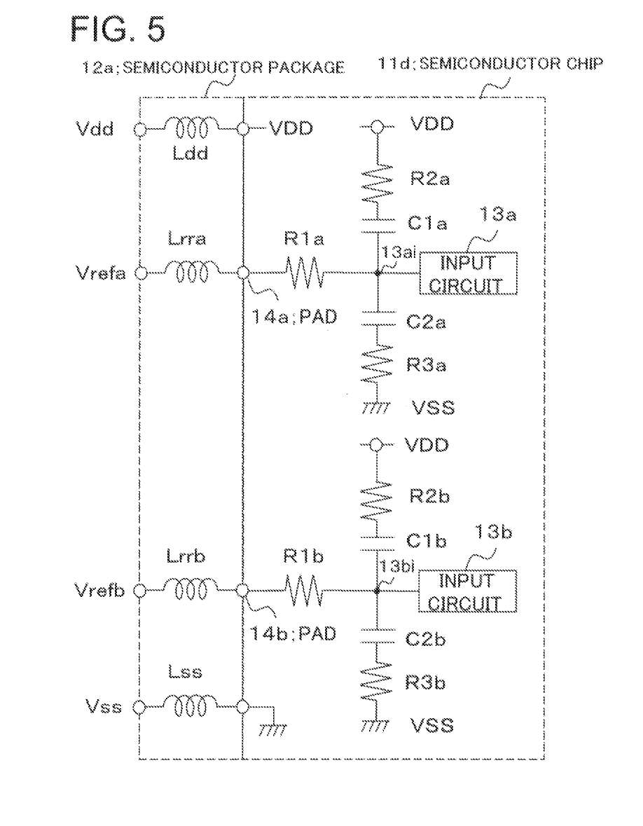

The above description was directed to a case where one kind of the reference voltage Vref is input. The invention, however, is not limited to this arrangement, and two or more kinds of the reference voltage Vref may be input, as described in the first example. FIG. 5 is a block diagram showing a configuration of a semiconductor device having two Vref inputs. Referring to FIG. 5, reference numerals that are the same as those in FIG. 2 indicate same components. A semiconductor chip 11d is obtained by inserting a resistance element R2a between the capacitance element C1a and the power supply VDD, inserting a resistance element R3a between the capacitance element C2a and the ground VSS, inserting a resistance element R2b between the capacitance element C1b and the power supply VDD, and inserting a resistance element R3b between the capacitance element C2b and the ground VSS, on the semiconductor chip 11b in FIG. 12.

In the semiconductor chip 11d having such a configuration, the resistance value of the resistance element R1a and resistance values of the resistance elements R2a and R3a should be set according to the self inductance Lrra and a difference between the capacitance elements C1a and C2a, where as the resistance value of the resistance element R1b and resistance values of the resistance elements R2b and R3b should be set according to the self inductance Lrrb and a difference between the capacitance elements C1b and C2b. A method of determining the respective resistance values of the resistance elements R1a, R2a, R3a. R1b, R2b, and R3b is the same as that as described before. In this example, the description was directed to the case where the two kinds of the reference voltage Vref are input. When three or more kinds of the reference voltage Vref are input, the same method may be used for setting.

Further, when a Vref sensitivity of the input circuit 13a is different between the high level side and the low level side, the capacitances of the capacitance elements C1a and C2a are adjusted according to the noise immunity voltages of the input circuit 13a, as in the second example. The noise margin when the noise sensitivity of the input circuit 13a is different between the high level side and the low level side can be thereby increased. Likewise, the capacitances of the capacitance elements C1b and C2b are also adjusted according to the noise immunity voltages of the input circuit 13b. The noise margin when a noise sensitivity of the input circuit 13b is different between the high level side and the low level side can be thereby increased. A method of determining the capacitances of the capacitance elements are the same as that in the second example, and setting of the resistance values is also performed as described before.

### EXAMPLE 4

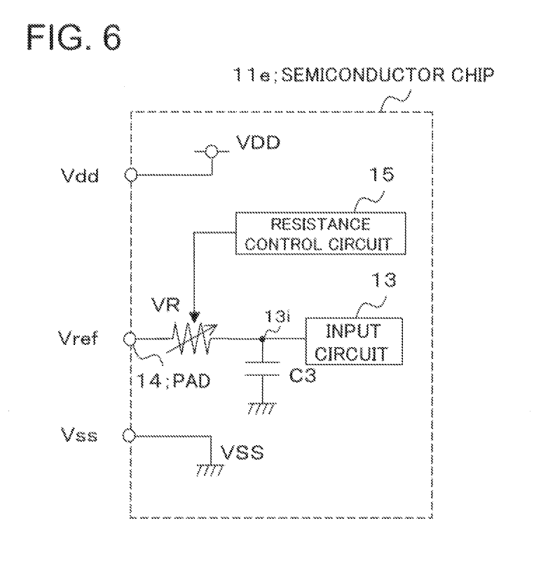

FIG. 6 is a circuit diagram showing a main portion of a semiconductor device according to a fourth example of the present invention. Referring to FIG. 6, same reference numerals as those in FIG. 1 indicate same components. Though a semiconductor package is not shown, it is assumed that the semiconductor package is present, as in FIG. 1. A semiconductor chip 11e includes an input circuit 13, a pad 14, a resistance control circuit 15, a variable resistance element VR, and a capacitance element (C3. The capacitance element C3 is inserted between the input end 13i of the input circuit 13 and the ground VSS. The variable resistance element VR connects the pad 14 and the input end 13i of the input circuit 13, and is controlled so that a resistance value thereof becomes variable by the resistance control circuit 15.

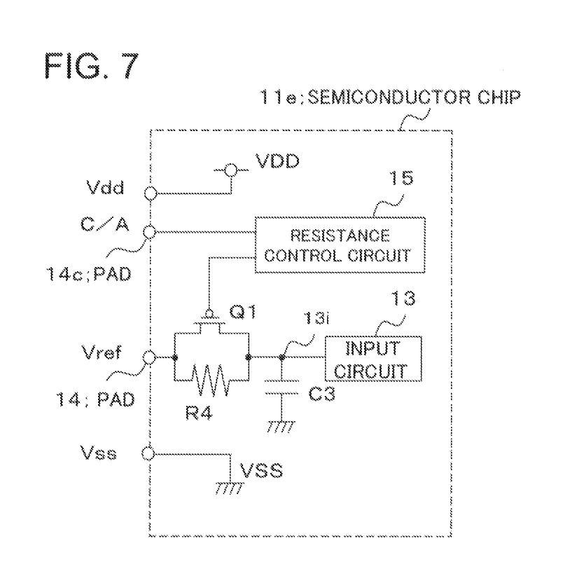

Next, an example of a specific configuration of the variable resistance element VR will be described. FIG. 7 is a circuit diagram showing a specific configuration of the variable resistance element VR in FIG. 6. The variable resistance element VR is formed of (or replaced by) a circuit in which a resistance element R4 is connected in parallel with, an MOS transistor Q1. A voltage at a control end of the MOS transistor Q1 is controlled by an output of the resistance control circuit 15.

The semiconductor chip 11e having such a configuration becomes effective in noise reduction especially when both of the power supply and the ground cannot be used for the capacitance element as a reference, unlike as shown in FIG. 1, and only one of the power supply and the ground can be used. The noise that poses the problem when only one of the power supply and the ground can be used is the differential mode noise at item (3). When only the ground VSS is used for the capacitance as the reference, for example, the noise vibrates as on the reference voltage Vref1 in FIG. 9. Accordingly, it happens that the noise margin becomes extremely small in the time period A (when the differential mode noise is induced).

In order to solve this problem. In this example, the resistance value of the variable resistance element VR is controlled so that the reference voltage assumes the intermediate potential regardless of fluctuation within the chip, like the reference voltage Vref 2 in FIG. 9, when the differential mode noise is induced. Specifically, at a timing when the differential, mode noise is induced, the resistance value of the variable resistance element VR is reduced, and the reference voltage Vref is referred to.

It is assumed herein that the resistance value of the variable resistance element VR assumes at least a value Rrrmin and a value Rrrmax, which are two values expressed by the following formulae:

Rrrmax=1/[2πCrs*fck] (13)

Rrrmin=2[(Lrr+Lss)/Crs]^{0.5} (14)

The value Rrmin is a resistance value when the differential mode noise is induced, and is a resistance value which reduces all the types of noise except the common mode noise of item (2) and the extraneous noise of item (5). The value Rrrmax is a resistance value which is set as a default when the differential mode noise does not occur, and which reduces all the types of noise except the differential mode noise of item (3). Depending on the semiconductor device, the value Rrrmin may be larger than the value Rrrmax. In such a case, however, this example is not effective. When the value Rrrmin is greatly different from, the value Rrrmax, it is preferred that certain number of intermediate values are taken and excitation of the noise current due to an abrupt resistance change is thereby suppressed.

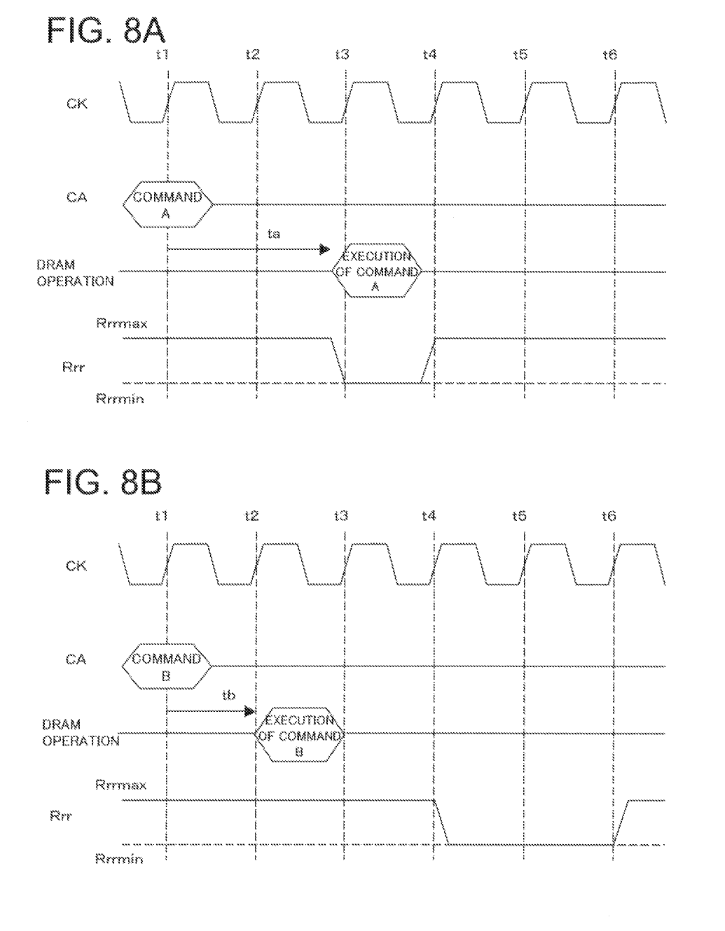

Next, examples of time charts for resistance value control over the variable resistance element VR by the resistance control circuit 15 will be shown in FIGS. 8A and 8B. Herein, an example where the semiconductor device is a DRAM will be taken and described. First, when the DRAM is turned on, the resistance value of the variable resistance element VR is set to the value Rrrmax. Then, when a command is input, it is checked whether the command is the one related to occurrence of the differential mode noise.

Among commands related to the differential mode noise in the case of the DRAM are precharge, refresh, and read commands. When these commands are broadly classified into a command (command A) that induces only the differential mode noise at a time of executing the command and a command (command B) that induces the common mode noise at a time of executing the command and then induces the differential mode noise, the precharge and refresh commands are classified into the command A, and the read command is classified into the command B.

A state of an operation when the command has been found to be the command A at a time of a command check will be shown in FIG. 8A. The resistance control circuit 15 changes the resistance value of the variable resistance element VR to the value Rrrmin after a time ta clasped from input of the command to execution of the command. Then, while the command is executed, the resistance control circuit 15 causes the resistance value to be kept at the value Rrrmin, and returns the resistance value to the value Rrrmax when an operation specified by the command is finished.

A state of an operation when the command has been found to be the command B at a time of the command check will be shown in FIG. 8B. First, for a time tb clasped from input of the command to actual execution of the command, the value Rrrmax is maintained, in this case, when a plurality of operations specified by input of one command (such as a read in a burst mode) are performed, the value Rrrmax is maintained until all the operations are finished. Further, after all the operations specified by the command have been finished, the value Rrrmax is maintained for one clock (from a timing t3 to a timing t4). This operation is performed in order to reduce an influence of the common mode noise (Off-Chip SSO noise) induced immediately after the read operation. At the timing t4 after the one clock, the resistance value is set to the value Rrrmin just for a required number of clocks. This required number of clocks is determined according to a time constant of the differential mode noise induced at a time of the read operation. When the time constant of the differential mode noise is twice as long as a time of the clock, the resistance value is set to the value Rrrmin for two clocks (from the timing t4 to a timing t6). Then (after the timing t6), the resistance value is returned to the value Rrrmax.

Next, the resistance control circuit 15 will be described. Referring to FIG. 7, the resistance control circuit 15 makes command type determination as to the command A or B based on an input C/A signal, and adjusts a timing using a flip-flop or the like provided within the resistance control circuit 15, thereby generating a signal that turns on or off the MOS transistor Q1. This on/off signal is sent to the control end (gate) of the MOS transistor Q1 for resistance control in the vicinity of the pad 14, and turns on or off the MOS transistor Q1. A resistance value of a Vref line between the pad 14 and the input circuit 13 is thereby changed. When the MOS transistor is turned on, a combined resistance, in parallel, of a resistance value Ra of the MOS transistor Q1 and the resistance value Rrrmax of the resistance element R4 becomes the resistance value of the Vref line. Accordingly, the resistance value Ra of the MOS transistor satisfies the following Formula (15).

Ra=Rrrmin*Rrrmax/(Rrrmax−Rrrmin) (15)

Control of the resistance value described above is the most effective when the following condition holds:

Condition (1): When a plurality of semiconductor devices are mounted on the same board, a propagation amount of Vref noise emitted by other semiconductor devices is sufficiently smaller than that of the Vref noise emitted from a certain semiconductor device. The propagation amount of the Vref noise from the other semiconductor devices is, for example, not more than 10% of that of the Vref noise caused by the certain semiconductor device itself.

### Condition (2): Rrrmax>> Rrrmin holds.

A system that handles a low-speed signal often satisfies the condition (2). When the resistance values Rrrmax and Rrrmin are found in the semiconductor device with a capacitance Crs of 5 pF, a clock frequency fck of 100 MHz, an inductance Lrr of 1 nH, an inductance Lss of 0.5 nH, and an inductance Ldd of 0.5 nH, the resistance value Rrrmax assumes 159Ω and the resistance value Rrrmin assumes 34.6Ω, which satisfies the condition (2).

On the other hand, in the case of a high-speed signal system, a cut-off frequency of the filter may be high. Thus, the resistance value Rrrmax may be small. As a result, the need for changing the resistance is almost eliminated.

The above description was given based on the DRAM as an example of the semiconductor device. The semiconductor device is not limited to a memory chip such as the DRAM. Various types of semiconductor devices that handle the reference voltage may be employed. Further, it is assumed that the semiconductor device handles binary logical values. The same concept may be applied to a multiple-valued logic semiconductor device that bandies the binary logical values or more multiple-valued logical values.

The invention can be applied to various semiconductor devices that handle the reference voltage Vref.

It should be noted that other objects, features and aspects of the present invention will become apparent in the entire disclosure and that modifications may be done without departing the gist and scope of the present invention as disclosed herein and claimed as appended herewith.

Also it should be noted, that any combination of the disclosed and/or claimed elements, matters and/or items may fall under the modifications aforementioned.

What is claimed is:

1. A semiconductor device comprising:
an input terminal that receives a reference voltage;
an input circuit;
a first resistance element connected between an input end of said input circuit and said input terminal;
a first capacitance element connected between said input end and a power supply line within the semiconductor device; and
a second capacitance element connected between said input end and a ground line within the semiconductor device.

2. The semiconductor device according to claim 1, wherein a resistance value of said first resistance element is set based on impedance characteristic of a wiring for supplying the reference voltage.

3. The semiconductor device according to claim 1, wherein a resistance value of said first resistance element is set to a largest resistance value among:
(a) a first resistance value of said first resistance element that causes a cut-off frequency of a low-pass filter formed of said first resistance element and said first and second capacitance elements connected in parallel to a clock frequency of the semiconductor device;
(b) a second resistance value of said first resistance element that causes a secondary circuit of a power supply wiring formed of a line of said reference voltage and a ground line to satisfy a requirement for overdamping; and
(c) a third resistance value of said first resistance element that causes a secondary circuit of a power supply wiring formed of a line of said reference voltage and said power supply line to satisfy a requirement for overdamping.

4. The semiconductor device according to claim 1, wherein said first capacitance element is replaced by a series connection circuit formed of said first capacitance element and a second resistance element, and said second capacitance element is replaced by a series connection circuit formed of said second capacitance element and a third resistance element.

5. The semiconductor device according to claim 1, wherein a capacitance ratio between said first capacitance element and said second capacitance element is set based on a noise sensitivity of said input circuit.

6. The semiconductor device according to claim 5, wherein the capacitance ratio is a ratio between, a noise immunity voltage when a voltage level at said input end of said input circuit assumes a level on a ground side and a noise immunity voltage when the voltage level at said input end of said input circuit assumes a level on a power supply side.

7. The semiconductor device according to claim 4, wherein a sum of resistance values of said first and second resistance elements is a value that causes a secondary circuit of a power supply wiring formed of a reference voltage line and said power supply line to satisfy a requirement for overdamping; and
a sum of resistance values of said first and third resistance elements is a value that causes a secondary circuit of a power supply wiring formed of said reference voltage line and said ground line to satisfy a requirement for overdamping.

8. A semiconductor device comprising:
an input terminal that receives a reference voltage;
an input circuit;
a variable resistance element connected between an input end of said input circuit and said input terminal;
a capacitance element connected between said input end and a power supply line or a ground line within the semiconductor device; and
a resistance control circuit that controls a resistance value of said variable resistance element.

9. The semiconductor device according to claim 8, wherein said variable resistance element comprises a MOS transistor with a voltage at a control terminal thereof controlled by said resistance control circuit.

10. The semiconductor device according to claim 8, wherein said resistance control circuit performs control so that a resistance value of said variable resistance element assumes at least two values comprising:
a resistance value of said variable resistance element that causes a cut-off frequency of a low-pass filter formed of said variable resistance element and said capacitance element to a clock frequency of the semiconductor device; and
a resistance value of said variable resistance element that causes a secondary circuit of a power supply wiring formed a reference voltage line and said power supply line to satisfy a requirement for overdamping when said, capacitance element is connected to said power supply line, and causes a secondary circuit of a power supply wiring formed of said reference voltage line and said ground line to satisfy a requirement for overdamping when said capacitance element is connected to said ground line.

11. The semiconductor device according to claim 8, wherein said resistance control, circuit controls the resistance value of said variable resistance element according to an operation mode or modes of the semiconductor device.

12. The semiconductor device according to claim 11, wherein the semiconductor device is a DRAM and the operation mode is specified by a command for said DRAM.

13. The semiconductor device according to claim 12, wherein said resistance control circuit controls the resistance value of said variable resistance element according to a time elapsed following generation of the command.

14. The semiconductor device according to claim 13, wherein said resistance control circuit performs control so that when the command belongs to a first command group, the resistance value of said variable resistance element is reduced during execution of the command, and when the command belongs to a second command group, the resistance value of said variable resistance element is reduced during a certain period of time after a predetermined time has passed since the execution of the command.
